(19) United States
(12) Patent Application Publication
(10) Pub. No.: US 2017/0069814 A1
(43) Pub. Date: Mar. 9, 2017

(54) DOPING PREFERENCES IN CONJUGATED POLYELECTROLYTE/SINGLE-WALLED CARBON NANOTUBE COMPOSITES

(71) Applicant: The Regents of the University of California, Oakland, CA (US)

(72) Inventors: Guillermo C. Bazan, Santa Barbara, CA (US); Cheng-Kang Mai, Goleta, CA (US)

(73) Assignee: The Regents of the University of California, Oakland, CA (US)

(21) Appl. No.: 15/256,215

(22) Filed: Sep. 2, 2016

Related U.S. Application Data
(60) Provisional application No. 62/213,782, filed on Sep. 3, 2015.

(51) Int. Cl. H01L 35/24; H01L 35/04

(52) U.S. Cl. CPC H01L 35/24; H01L 35/04

(57) ABSTRACT

A method of fabricating a doped composite including combining one or more carbon nanotubes with one or more Conjugated Polyelectrolytes (CPEs) to form a composite, wherein charge transfers between one or more of the CPEs and one or more of the carbon nanotubes, and the CPEs and/or a relative content of the carbon nanotubes in the composite are selected to obtain the composite that is n-type or p-type doped.

### CROSS REFERENCE TO RELATED APPLICATIONS

This application claims the benefit under 35 U.S.C. Section 119(e) of co-pending and commonly-assigned U.S. Provisional Patent Application No. 62/213,782, filed Sep. 3, 2015, by Guillermo C. Bazan and Cheng-Kang Mai, entitled “DOPING PREFERENCES IN CONJUGATED POLYELECTROLYTE/SINGLE-WALLED CARBON NANOTUBE COMPOSITES,” Attorney's Docket No. 30794.595-US-P1 (U.C. Ref. 2015-546-1), which application is incorporated by reference herein.

### STATEMENT REGARDING FEDERALLY SPONSORED RESEARCH AND DEVELOPMENT

This invention was made with Government support under Grant No. MURI FA 9550-12-0002 awarded by the AFOSR to Guillermo C. Bazan. The Government has certain rights in this invention.

### BACKGROUND OF THE INVENTION

1. Field of the Invention

This invention relates to a composition of matter comprising a doped conjugated polyelectrolyte/single-walled carbon nanotube composite and method of fabrication thereof.

2. Description of the Related Art

(Note: This application references a number of different publications as indicated throughout the specification by one or more reference numbers and/or letters in brackets (e.g., [x]). A list of these different publications ordered according to these reference numbers can be found below in the section entitled “References.” Each of these publications is incorporated by reference herein.)

Single-walled carbon nanotubes (SWNTs) are attractive materials for developing flexible organic electronics [1], given their outstanding chemical [2], electrical [3], and mechanical properties [4]. As synthesized, SWNTs exist as bundles due to the strong inter-tube interactions. To enable solution processing, a variety of conjugated polymers have been used as SWNT dispersants [5]. Conjugated polyelectrolytes (CPEs), namely conjugated polymers with pendant ionic functionalities, are particularly interesting [6]. They not only provide hydrophobic interactions between the conjugated backbones and the SWNT surfaces, but also render the CPE/SWNT complexes miscible in polar solvents due to the presence of ionic functionalities. The optical, mechanical, and electrical properties of these composites can be tailored without negatively impacting the desirable electronic properties of SWNTs. Such non-covalent composite systems, when there is no covalent bond between the CPE and the SWNT, can therefore be preferable to counterparts that include modifications of SWNTs via chemical reactions [7].

SWNT composites have found a variety of useful applications, such as optical probes for bioanalytical sensors [8], organic solar cells [9], field-effect transistors (FETs)[10], and thermoelectrics [11]. Pristine SWNTs frequently exhibit p-type charge transport behavior, due to hole generation upon oxidation by air, and most SWNT composites are typically p-type materials [12]. However, both p-type and n-type materials are desired for many organic electronic device, such as for thermoelectric modules [13] and field-effect transistors [14]. SWNTs can be intentionally n-type doped via reduction with potassium [15], but the stability of the resulting materials may be insufficient for long term device applications. Metal-encapsulated carbon nanotubes [16], and non-covalent functionalization of SWNTs with electron-rich polymers [10 (a), 11(e)-(j) or small molecules [11(k)] also provide n-type SWNT composites, which are usually processed as buckypapers via filtration. While CPEs have been shown to aid the solution-processability of SWNTs, their use as charge-transfer dopants for SWNTs has not been reported [5b].

One or more embodiments of the present invention disclose the selective doping of SWNTs by CPEs to provide either p- or n-type composites, via a process that is dictated by the choice of ionic functional group. Specifically, it is possible to use anionic and cationic CPEs with the same conjugated backbone to provide p-type and n-type conductive composites, respectively.

### SUMMARY OF THE INVENTION

One or more embodiments of the present invention disclose a method of fabricating a doped composite, comprising combining one or more carbon nanotubes with one or more Conjugated Polyelectrolytes (CPEs), wherein charge transfers between one or more of the CPEs and one or more of the carbon nanotubes, and a relative content of the carbon nanotubes in the composite is selected such that the composite is n-type or p-type doped.

The present invention has discovered that single-walled carbon nanotubes can be selectively doped by CPEs to form either p- or n-type conducting composites. The selectivity of charge-transfer doping is found to be dictated by the polarities of CPE pendant ionic functionalities. For example, anionic CPEs can be selected (e.g., CPEs having anionic side groups) to provide p-doping of SWNTs, while cationic CPEs (e.g., CPEs having cationic side groups) can be selected to provide n-doping of the SWNTs. CPEs can be selected based on Electron Affinity (EA) and/or Ionization Energy (IE) to selectively dope (p- vs n-type) SWNTs, e.g., in one or more embodiments, CPEs with IE<5.6 electron volts (eV) and EA>2.7 eV can selectively dope the SWNT depending/based on the choice of pendant ionic functionalities. For example, CPEs having |EA|>2.7 eV can behave asp-type dopants for SWNTs and be selected to provide p-doped composites, whereas CPEs having IE<5.6 eV can behave as n-type dopants for the SWNTs and be selected to provide n-type doped composites.

The composite can be formed by mixing the CPEs and nanotubes to form an aqueous mixture, and then casting the mixture on a substrate using spin-coating, drop-casting, or injection-printing to form a flexible electronic device or circuit. In addition, the CPEs can be used to increase solubility of, and/or act as a dispersant for, the carbon nanotubes in the aqueous mixture.

In one or more embodiments, the composite is processed from a dispersion cast on a substrate and the relative content (of CPEs and carbon nanotubes) is selected to achieve specific device properties. In one or more embodiments, the ratio of a weight of the CPEs to a weight of the carbon nanotubes in the composite is between 1:1 and 2:3, is such that an n-type conductivity of the composite is at least 100 Siemens per centimeter, or is such that a p-type conductivity of the composite is at least 500 Siemens per centimeter.

In one or more embodiments, a thermoelectric device comprising the composite generates electric current in response to a temperature gradient and the relative content of the CPEs and carbon nanotubes provide a thermoelectric performance characterized a power factor of at least 218 μW m⁻¹ K⁻² for a p-type doped composite, or a power factor of at least 17 μW m⁻¹ K⁻² for an n-type doped composite.

### BRIEF DESCRIPTION OF THE DRAWINGS

Referring now to the drawings in which like reference numbers represent corresponding parts throughout:

FIG. 1a illustrates chemical structures of the studied CPEs, wherein pendant ionic functionalities and counterions are colored, negatively charged counterions are blue, and positively charged counterions are red, FIG. 1b illustrates the synthesis of PCPDTBT-Pyr⁺BIm₄⁻(CPE-PyrBIm₄), and FIG. 1c illustrates the synthesis of PCPDTBTSO₃K (CPE-Na).

FIGS. 2a-2b plot electrical conductivity (σ, black); Seebeck coefficient (S, blue); and power factor (PF=σS², red) as a function of different weight ratios for PFBT-Na/SWNT (FIG. 2a) and CPE-Na/SWNT (FIG. 2b), according to one or more embodiments of the present invention, wherein [CPE]=2 mg mL⁻¹ is constant in all dispersions and σ and PF are plotted on a log scale, while S is plotted on a linear scale, according to one or more embodiments of the present invention.

FIGS. 3a-3d show Scanning Electron Microscopy (SEM) images of CPE-Na/SWNT films (cross-section) for different weight ratios on silicon and according to one or more embodiments of the present invention, wherein FIG. 3a shows the SEM of the film comprising a 2:1 weight ratio (spin-coating); FIG. 3b shows the SEM of the film comprising a 1:1 weight ratio (spin-coating); FIG. 3c shows the SEM of the film comprising a 2:3 weight ratio (spin-coating); and FIG. 3d shows the SEM of the film comprising a 2:3 weight ratio (drop-casting).

FIGS. 4a-b plot electrical conductivity (σ, black); Seebeck coefficient (S, blue); and power factor (PF=σS², red) as a function of different weight ratios for PFBT-PyrBIm₄/SWNT (FIG. 4a) and CPE-PyrBIm₄/SWNT (FIG. 4b) according to one or more embodiments of the present invention, wherein [CPE]=2 mg mL⁻¹ is constant in all dispersions and σ and PF are plotted on a log scale, while S is plotted on a linear scale.

FIG. 5 plots thermoelectric properties of CPE-PyrBIm₄/SWNT composite spin-coated films ([SWNT]=2 mg/mL) as a function of CPE-PyrBIm₄ concentration in dispersions, according to one or more embodiments of the present invention, wherein plotted values correspond to the average of three independent measurements.

FIG. 6 is a flowchart illustrating a method of fabricating a doped composite according to one or more embodiments of the invention.

FIG. 7a illustrates a radial thermoelectric generator in a planar module configuration which can be utilized to harness radial thermal gradients generated from a localized hot spot, according to one or more embodiments of the invention, FIG. 7b shows open-circuit voltage (Voc) increases as more p- and n-legs are added in series to assemble the module under a temperature gradient (ΔT=10 K as determined using an infra-red camera), and FIG. 7c shows power generation by the 8-leg module shown in FIG. 7a under varied temperature gradients.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Technical Description

### Example Structures and Fabrication

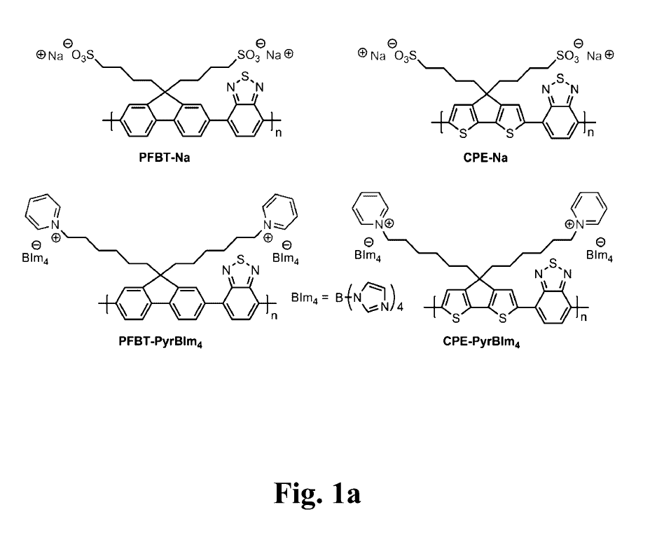

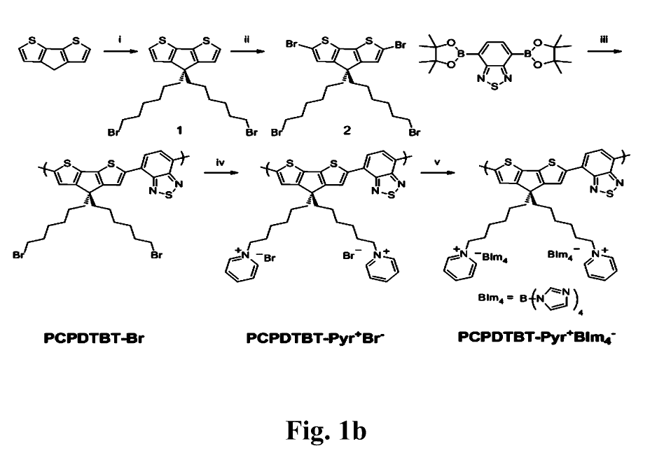

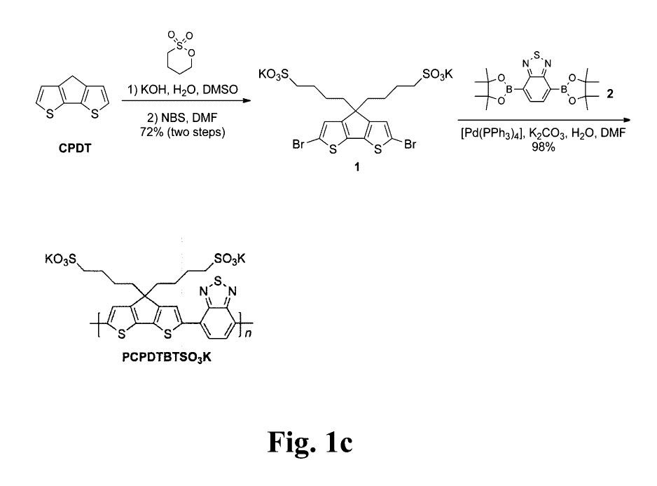

FIG. 1a provides the molecular structures of the four CPEs included in our studies. Detailed synthetic procedures and characterization are provided in our publications [17].

FIG. 1b shows the synthesis of PCPDTBT-Pyr⁺BIm₄⁻(CPE-PyrBIm₄), comprising Suzuki cross-coupling polymerization of an alkyl bromide-substituted cyclopentadithiophene and the bis-boronic ester of benzothiadiazole to generate the neutral precursor polymer, PCPDTBT-Br. Post-polymerization quaternization with pyridine introduces the cationic functionalities and yielded PCPDTBT-Pyr⁺Br⁻. As a final chemical modification, the bromide counterions in PCPDTBT-Pyr⁺Br⁻were exchanged with the larger tetrakis(1-imidazolyl)borate (BIm₄⁻) anion to provide PCPDTBT-Pyr⁺BIm₄⁻.

FIG. 1c shows the synthesis of PCPDTBTSO₃K (an analogue of CPE-Na while the counterion Na⁺ is replaced by K⁺. Synthesis of CPE-Na follows the same procedure), comprising alkylation of commercially available cyclopentadithiophene (CPDT) with 1,4-butanesultone under basic conditions, followed by bromination using N-bromosuccinimide (NBS), providing a water-soluble monomer 1. Suzuki coupling of the water soluble monomer and commercially available bispinacolate 2 in a DMF/H₂O solvent mixture affords the target PCPDTBTSO₃K. For purification, PCPDTBTSO₃K was precipitated in acetone, filtered, washed with copious amounts of acetone and methanol, and subjected to dialysis in water for three days. The molecular weight cut off of the dialysis membrane is 3500-5000 Da. After drying under vacuum, the product is obtained as a dark blue solid. The ionic nature of PCPDTBTSO₃K renders it soluble in water and insoluble in polar organic solvents, such as CH₃CN, MeOH, DMF, and DMSO.

PFBT-Na and PFBT-PyrBIm₄ share the same conjugated backbone, poly(fluorene-alt-benzothiadiazole) (PFBT), but contain tethered anionic (sulfonates) and cationic (pyridinium) groups, respectively. Similarly, CPE-Na and CPE-PyrBIm₄ possess the narrow bandgap conjugated backbone, poly(cyclopenta-[2,1-b;3,4-b′]-dithiophene-alt-4,7-(2,1,3-benzothiadiazole)) (CPDT-alt-BT), but contain different ionic groups. These four polymers provide a unique opportunity to untangle the influence of the conjugated backbone and the pendant ionic functionalities on electronic properties.

In order to prepare CPE/SWNT dispersions, purified arc discharge SWNTs (P2-SWNT) were purchased from Carbon Solutions, Inc. (Riverside, Calif., USA) and used without any further purification. Different amounts of SWNT powder were added into the CPE solutions (2 mg mL⁻¹ in 1:1 H₂O:MeOH) to provide CPE:SWNT at different weight ratios. SWNTs were dispersed using probe sonication (SONICS, VCX-130) at 85 W in a water-ice bath for 1 hour (h).

The CPE/SWNT composite films were characterized by measurements of electrical conductivity (σ) and Seebeck coefficient (S) under nitrogen. Standard four point probe measurements were used to measure σ. As described in more detail in the supporting information [23], S was determined by linear fitting of data taken by imposing temperature differences ΔT across the sample and measuring the corresponding thermovoltages ΔV (S=−ΔV/ΔT). The selectivity of the doping is verified by the sign of the S values, of which positive and negative signs indicate p- and n-type charge transport, respectively [13]. Power factors (PF=σS²) were calculated accordingly.

Comparison of PFBT-Na and CPE-Na

The influence of the conjugated backbone (PFBT-Na vs. CPE-Na) on the properties of anionic CPE/SWNT composites can be compared. It is worth noting that CPE-Na is readily doped during dialysis in water leading to conductive films [17(b),18], while PFBT-Na remains neutral and thus leads to relatively insulating films due to the low density of free charge carriers. The inventors of the present invention therefore expected to observe different electrical behavior for these blends using polymers with the same ionic side chains and counterions, but different conjugated backbones.

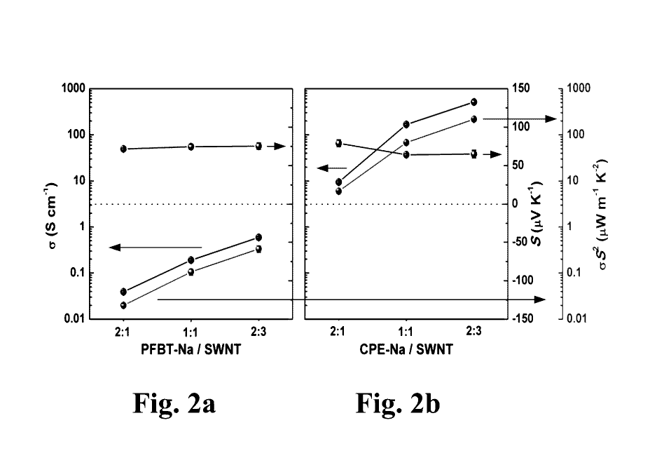

The electrical conductivity and relevant thermoelectric properties of PFBT-Na/SWNT composites at different weight ratios are shown in FIG. 2a. One observes that a increases progressively as the SWNT loading increases. S remains positive, which is indicative of p-type conduction, and is not affected by the range of loadings examined in these studies. The PF values therefore increase because of the increase in σ. In homogeneous semiconductors one typically finds an inverse relationship of σ and S, due to the increase in carrier concentration with larger electrical conductivity [13]. However, in heterogeneous materials, such as composites, this relationship does not necessarily hold due to the percolation of charge carriers through the two materials and across interfaces [19]. The insensitivity of S in these blends to different loadings, and the similarity of the values (˜65 μV/K) to that observed in the SWNT-only sample (62 μV/K, see Table 2, entry 5)[11], suggest that the SWNTs dominate S in the PFBT-Na/SWNT blends.

A different behavior is observed with CPE-Na/SWNT blends (FIG. 2b). As discussed above, CPE-Na is p-doped in solution, and therefore, one can measure σ (0.16±0.005 S cm⁻¹) and S (165±25 μV K⁻¹) for neat CPE-Na films [20]. Incorporation of SWNTs at the lowest ratio in our studies, i.e. CPE-Na/SWNT=2:1 by weight, yields an approximately 60-fold increase in σ. The value of σ continues to increase as the SWNT content increases, and reaches 514±55 S cm⁻¹ at the 2:3 weight ratio. Similar to the case of PFBT-Na/SWNT composites, S remains largely unchanged. The similar values to the PFBT-Na/SWNT blends, where the polymer is undoped, suggest that S is again dominated by the SWNTs. The doped nature of CPE-Na likely increases the electrical conductivity by reducing the inter-SWNT contact resistance. The higher σ of CPE-Na/SWNT composites, relative to PFBT-Na/SWNT, leads to a larger PF, reaching up to 218±89 μW m⁻¹ K⁻² at the 2:3 weight ratio. This is the highest PF value obtained in all of the CPE/SWNT blends examined in our studies. It should be noted that efforts to increase [SWNT] in the parent dispersions led to high viscosity, which prevented processing of the composites.

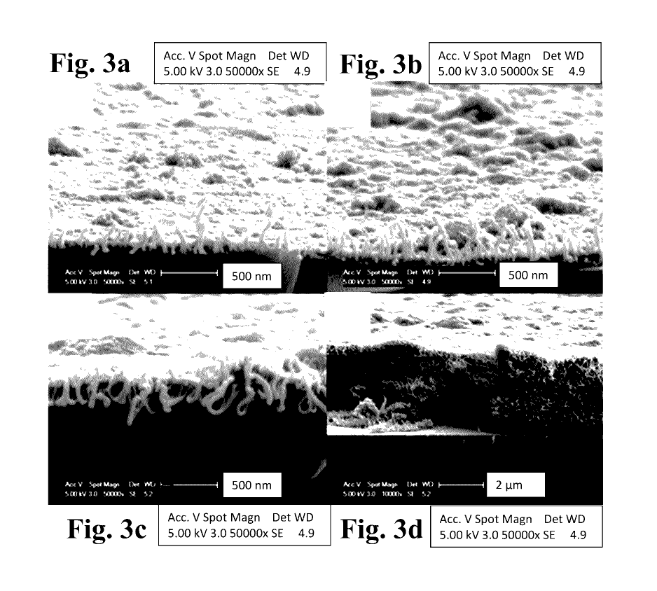

Scanning electron microscopy (SEM) images of CPE-Na/SWNT films deposited on silicon substrates as a function of composition are provided in FIGS. 3a-3d. These data show that the composite films are heterogeneous, and that they become more densely packed at higher loadings, leading to a large number of inter-SWNT contacts. Also provided in FIG. 3d is the image of a much thicker film that was prepared by drop-casting from a 2:3 weight ratio of CPE-Na/SWNT in MeOH/water (1:1 vol:vol). One can therefore tune the thickness of the active layer depending on the desired applications.

Doping Selection

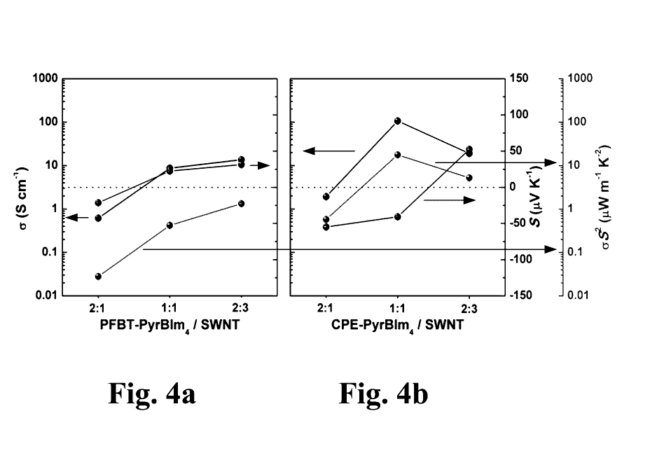

Surprisingly, the inventors find that the charge carrier type in the blends can be switched by changing the side chains and counterions in the CPE structure. The electronic characteristics of PFBT-PyrBIm₄/SWNT and CPE-PyrBIm₄/SWNT, which have cationic side chains, are very different from their anionic counterparts (FIGS. 4a-b). Analysis begins by examinations of S. At low SWNT content, the negative S values measured for PFBT-PyrBIm₄/SWNT (−21±3 μV K⁻¹ at 2:1 weight ratio) and CPE-PyrBIm₄/SWNT (−55±8 μV K⁻¹ at 2:1) indicate that the predominant charge carriers in the composites are electrons. Therefore, these cationic CPEs behave like n-type dopants [21]. CPE-PyrBIm₄ appears to be a more persistent n-type dopant, because the composite retains the negative coefficient at 1:1 content (−41±6 μV K⁻¹). At the highest SWNT content (2:3 CPE/SWNT weight ratio), both CPE-PyrBIm₄ (52±8 μV K⁻¹) and PFBT-PyrBIm₄ (31±5 μV K⁻¹) composites regain the p-type transport, which is characteristic of the carbon nanotubes themselves. These observations thus reveal the ability to tune the predominant charge carrier in the composite via the ratio of the components.

FIGS. 4a-4b also reveals a complex behavior for σ in the cationic CPE/SWNT films, particularly for CPE-PyrBIm₄/SWNT, for which a maximum is observed in the 1:1 blend. The inventors' working hypothesis is that CPE-PyrBIm₄ can n-dope the nanotubes and a higher n-type charge carrier density is therefore achieved when the SWNT content is lower. The SWNTs will still likely provide the dominant contribution to σ due to their higher charge mobility. S is a weighted average of the contributions of holes and electrons, and it is possible that the relatively lower values of S in these blends vs. those of PFBT-Na and CPE-Na (˜65 μV K⁻¹) are due to the competition between p- and n-type conductions. As the amount of SWNTs increases, one observes a shift to overall p-type transport in the 2:3 system. These observations suggest that the conventional p-doping of the SWNT is no longer compensated by n-type doping by the cationic CPEs. Under these scenarios, less efficient doping by CPE-PyrBIm₄ in the 2:3 composite possibly results in a lower effective charge carrier density, thus leading to a lower σ (19±1 S cm⁻¹). Therefore, the highest PF obtained for the n-type CPE-PyrBIm₄/SWNT composite is 17.8±5.8 μW m⁻¹ K⁻² in the 1:1 blend.

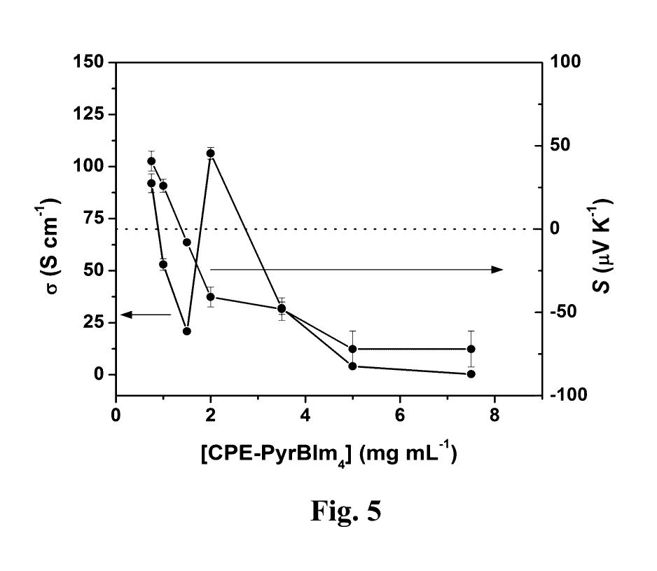

That CPE-PyrBIm₄ is an n-type dopant for SWNTs is substantiated by examination of composites prepared from dispersions with constant [SWNT]=2 mg mL⁻¹ and varying [CPE-PyrBIm₄]. FIG. 5 shows the change of σ and S as a function of [CPE-PyrBIm₄]. As [CPE-PyrBIm₄] increases, S gradually decreases, turns into negative values, and finally stabilizes at −72±11 μV K⁻¹. The interpretation of σ is nontrivial. When [CPE-PyrBIm₄]=0.75 mg mL⁻¹, α=92±6 S cm⁻¹, which is the highest σ of the p-type composites. As [CPE-PyrBIm₄] increases, the hole concentration in the composites decreases, and results in a local minimum of σ at [CPE-PyrBIm₄]=1.5 mg mL⁻¹, at which point, the absolute value of S is also the minimum. Further increase of [CPE-PyrBIm₄] leads to n-type composites, and a maximum σ is observed at [CPE-PyrBIm₄]=2 mg mL⁻¹. Similar behaviors are also observed in n-type SWNT composites with molecular dopants [11(k)], and this can explain why higher [SWNT] provides a lower σ in the CPE-PyrBIm₄/SWNT (2:3) system in FIG. 4b, because of the switch of the predominant charge carriers. However, overloading of CPE-PyrBIm₄ will dilute inter-SWNT contacts to provide less conducting materials with stable negative S at −72±11 μV K⁻¹. Overall, this study indicates that a careful tuning of the amount of n-type dopants is required in order to obtain SWNT composites with high σ while retaining the negative S.

Examination of the ionization energies (IE) and electron affinities (EA) of the CPEs provides a basis to understand the charge-transfer doping of SWNTs (Table 1). IEs were obtained by ultraviolet photoelectron spectroscopy (UPS) measurements, while EAs were estimated by subtracting the optical bandgap from the IE. Interestingly, for PFBT-Na (IE=5.4 eV, |EA|=3.0 eV) and PFBT-PyrBIm₄ (IE=5.5 eV, |EA|=3.2 eV) with the same conjugated backbones, pendant ionic functionalities do not change the IE and EA significantly. The narrow bandgap cationic CPE-PyrBIm₄ (IE=4.7 eV, |EA|=3.3 eV) displays a similar EA, but a lower IE due to the electron-rich CPDT monomer units. It is known from the literature [11(k)] that molecular dopants with |EA|>2.7 eV can behave as p-type dopants for SWNTs, while molecules with IE<5.6 eV can n-dope effectively [11(k)]. Under this scenario, PFBT-Na, PFBT-PyrBIm₄ and CPE-PyrBIm₄ have the potential to serve as either p-type or n-type dopants for SWNTs. The pendant charged groups of CPEs enable functionality beyond providing the solubility in polar media. Note also that CPE-Na is not included in these considerations because it is intrinsically doped.

A series of control experiments were conducted to further understand the n-type doping capability of CPEs with -PyrBIm₄ functionality. First, it is noted that PFBT-PyrBIm₄ is synthesized via a two-step sequence (see scheme S1 in the Supporting information [23]). A CPE analogue PFBT-PyrBr with Br counterions is the precursor to PFBT-PyrBIm₄. With PFBT-PyrBr in hand, both σ and S of composite PFBT-PyrBr/SWNT at different weight ratios were measured (Table 2, entries 1, 3 and 4). Negative S was observed only at high [PFBT-PyrBr] (entry 4), at which point σ (0.0076 S cm⁻¹) is too low to be useful in a thermoelectric application. Considering the structural difference between PFBT-PyrBr and PFBT-PyrBIm₄ (FIG. 4a), the Pyr⁺-BIm₄⁻ ion pair seems to be a more potent element to contribute to n-type SWNT doping.

TABLE 1
Ionization energy (IE) and electron affinity (EA)
determined for the CPEs in this study.

| | IE | \|EA\| | Optical Bandgap |
|---|---|---|---|
| CPE | (eV)^{a} | (eV)^{b} | (eV)^{c} |
| PFBT-Na | 5.4 | 3.0 | 2.44 |
| PFBT- | 5.5 | 3.2 | 2.32 |
| PyrBIm₄ | | | |
| CPE- | 4.7 | 3.3 | 1.38 |
| PyrBIm₄ | | | |

^{a}Obtained from Ultraviolet Photoelectron Spectroscopy (UPS) measurements;
^{b}Estimated by subtracting the optical bandgap from the LE;
^{c}Estimated from the onset of thin film absorption.

One possible hypothesis to consider is that the BIm₄⁻ ion could be an effective dopant. However, a control experiment of SWNT with NaBIm₄ (1:1 by weight, see Fig. S7 in the Supporting Information [23] for X-ray photoelectron spectroscopy (XPS) analysis) does not show any significant change in either σ or S (Table 2, entries 5 and 6). BIm₄ on its own is not an apparent n-type dopant for SWNTs.

TABLE 2
Thermoelectric properties (σ and S) of PFBT-PyrBr/SWNT
composites and SWNT mats.

| | | | | σS² |
|---|---|---|---|---|
| Materials | | σ (S cm⁻¹) | S (μV K⁻¹) | (μW m⁻¹ K⁻²) |
| 1^{a} | PFBT-PyrBr/SWNT | 0.80 ± 0.04 | 78 ± 12 | 0.49 ± 0.17 |
| | (2:1) | | | |
| 2^{a} | PFBT-PyrBr/SWNT/ | 2.4 ± 0.1 | −13 ± 2 | 0.041 ± 0.014 |
| | NaBIm₄ (2:1:1) | | | |
| 3^{a} | PFBT-PyrBr/SWNT | 0.020 ± 0.001 | 78 ± 12 | 0.012 ± 0.004 |
| | (3:1) | | | |
| 4^{a} | PFBT-PyrBr/SWNT | 0.0076 ± 0.0004 | −113 ± 17 | 0.0097 ± 0.0034 |
| | (5:1) | | | |
| 5^{b} | SWNT | 18.5 ± 0.9 | 62 ± 9 | 7.1 ± 2.5 |
| 6^{b} | SWNT/NaBIm₄ (1:1) | 21.0 ± 1.0 | 59 ± 9 | 7.3 ± 2.6 |

^{a}[PFBT-PyrBr] = 2 mg mL⁻¹ in all dispersions.
^{b}SWNT mats (~20 μm thick) were prepared by filtration of SWNT dispersion in H₂O:MeOH (1:1) on top of filter papers (cellulose acetate, pore size = 0.45 μm).

Another factor to consider is that the dipole of the Pyr⁺-BIm₄⁻ ion pair facilitates the electron transfer from CPE to SWNT. Compared to the Br⁻ ion, BIm₄⁻, known as a bulky, non-coordinating counterion, has a longer distance from the Pyr⁺ cation, thus forming a larger dipole moment. This large dipole may account for the n-type SWNT doping. Interestingly, adding NaBIm₄ to the PFBT-PyrBr/SWNT (2:1) dispersion converts the original p-type composite into n-type, concomitant with the formation of the Pyr⁺-BIm₄⁻ ion pair. These observations highlight that the chemical nature of the ion pair is essential for determining the dopant strength. Without being bound by a specific scientific theory or mechanism of action, the inventors believe the exact spatial organization (i.e. distance between the CPE backbone and SWNT surface, orientation/location of the electrostatic dipoles) can account for the forces of interactions that come together for favoring one type of charge carrier relative to the other.

Thus, one or more embodiments of the invention demonstrate the selective charge-transfer doping of SWNTs by using CPEs with identical conjugated backbone but different pendant ionic functionalities. Specifically, CPEs with anionic or cationic side chains provide p-type or n-type conductive CPE/SWNT composites, respectively, at non-excess loadings of SWNTs. The inventors of the present invention find that using the self-doped [22] CPE-Na as the dispersing agent leads to composites with relatively high conductivity, because of the minimization of inter-SWNT contact resistance in the composite. Remarkably, the cationic CPE/SWNT composites exhibit negative S, indicative of n-type doping of the SWNT. Due to the synthetic versatility of cationic CPEs, our studies provide a new strategy to obtain n-type SWNT composites. Importantly, these CPE/SWNT composites are capable of solution-processing from aqueous mixtures, such as spin-coating, drop-casting, and possibly injection-printing, all of which are highly desirable for the future printed flexible electronics.

Process Steps

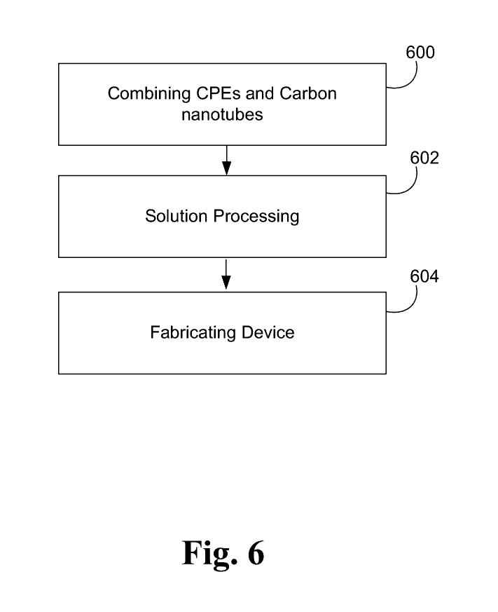

FIG. 6 illustrates a method of fabricating a doped composite according to one or more embodiments of the invention. The method comprises the following steps.

Block 600 represents combining one or more carbon nanotubes with one or more Conjugated Polyelectrolytes (CPEs) to form a (e.g., doped) composite, wherein charge transfers between one or more of the CPEs and one or more of the carbon nanotubes. In one or more embodiments, the one or more carbon nanotubes are electrically/electrostatically coupled to one or more of the CPEs. The CPEs and/or a relative content of the carbon nanotubes in the composite are selected to obtain the composite that is n-type or p-type doped.

In one or more embodiments, the CPEs are doped in a solution prior to being combined with the carbon nanotubes. In one example, the combining comprises mixing the CPEs and nanotubes to form an aqueous mixture. In one or more embodiments, the CPEs and the relative content increase solubility of, and/or act as a dispersant for, the carbon nanotubes in the aqueous mixture.

In one or more embodiments, the relative content is such that a ratio of a weight of the CPEs (in the composite) to a weight of the carbon nanotubes (in the composite) is 1:1 or more. In one or more embodiments of the invention, more CPEs will make the composite more processable.

In one or more embodiments, the maximum processable SWNT concentration is 60% by weight (˜2:3 CPE:SWNT), so that the SWNT concentration is in a range of more than 0% to 60% (the minimum SWNT concentration is typically greater than 0 and determined by the desired electrical conductivity; if the SWNT concentration is too low, the electrical conductivity will be too low for practical application).

In one or more embodiments, the CPEs comprise a poly(cyclopenta-[2,1-b;3,4-b′]-dithiophene-alt-4,7-(2,1,3-benzothiadiazole)) (CPDT-alt-BT) backbone with anionic or cationic side groups, e.g., CPE-Na, a CPE having a sulfonate side group, CPE-PyrBIm₄, or a CPE having a pyridinium side group (where the CPE is CPDT-alt-BT).

Any conjugated polymers with electron affinity |EA|>2.7 eV, and/or ionization energy IE<5.6 eV could be used as the CPE backbone. Specific examples include but not limited to conjugated homepolymers poly(3-hexylthiophene) (P3HT), Poly[2,5-bis(3-tetradecylthiophen-2-yl)thieno[3,2-b]thiophene] (PBTTT), and conjugated donor-acceptor copolymers with acceptor units selected from table 1 of U.S. Pat. No. 9,293,708 B2 [25] and donor units selected from table 2 of U.S. Pat. No. 9,293,708 B2 [25], and the conjugated polymers listed in table 51 of reference [26]. Any semiconducting polymer with a bandgap 5.6-2.7=2.9 eV will meet the requirement EA>2.7 eV (roughly the lowest unoccupied molecular orbital (LUMO)) or IP<5.6 eV (roughly the Highest Occupied Molecular Orbital (HOMO)).

CPEs having cationic side groups or chains (e.g., pyridium) can form an n-type doped composite with predominantly n-type conductivity (i.e., more n-type conductivity than p-type conductivity) when suitably combined with the one or more carbon nanotubes. Besides pyridium side chains, tetra-alkyl ammonium (cationic) side chains on the CPEs can also provide n-type doping of SWNTs.

CPEs having anionic (e.g., sulfonate) side groups can form a p-type doped composite having predominantly p-type conductivity (i.e., more p-type conductivity than n-type conductivity) when suitably combined with the one or more carbon nanotubes. Examples include, but are not limited to, CPE-Na.

In one or more embodiments, the CPEs are selected based on an optical bandgap, ionization energy, electron affinity, or dipole moment of the CPEs to achieve the composite having the desired n-type or p-type doping level. It is known from the literature [11(k)] that molecular dopants with electron affinity (|EA|>2.7 eV) can behave as p-type dopants for SWNTs, while molecules with ionization energy (IE<5.6 eV) can n-dope effectively [11(k)]. Any CPEs that meet these two requirements can selectively dope (p- vs. n-type) SWNTs, depending on the choice of pendant ionic functionalities. Specifically, as discussed above, anionic CPEs provide p-doping of SWNTs, while cationic CPEs provide n-doping.

Moreover, the doping strength can also be tailored (e.g., by careful tuning of the relative amount of the CPEs in the composite). Thus, one or more embodiments of the invention can selectively control doping and solution processability of the composites by the choice of CPE pendant charges.

Block 602 represents (e.g., solution) processing the composite onto a substrate.

In one or more embodiments, the substrate comprises at least one film or foil selected from a polyimide film, a polyether ether ketone (PEEK) film, a polyethylene terephthalate (PET) film, a polyethylene naphthalate (PEN) film, a polytetrafluoroethylene (PTFE) film, a polyester film, a metal foil, a flexible glass film, and a hybrid glass film, for example.

The step can comprise casting the mixture of CPEs and nanotubes on a substrate using spin-coating, drop-casting, or injection-printing.

The step can comprise coating/casting a dispersion comprising the CPEs and the nanotubes on a substrate; and annealing/drying/curing the dispersion (or allowing the dispersion to dry) to form a film on the substrate. In one or more embodiments, the dispersions are stable upon sitting for at least three months without apparent precipitation. The particle sizes in the dispersions can be selected depending on the application. One or more thermometric embodiments of the invention require a large quantity of SWNTs in the composite and the SWNTs are not fully de-bundled (although the SWNTs may also be fully de-bundled in one or more examples).

Block 604 represents fabricating a device comprising the composite. The step includes providing/connecting electrical contacts (e.g., source, drain, gate, other electrodes) on the film comprising the composite, to form the device. In one or more embodiments, the combination of substrate, composite, and electrodes is flexible.

In one or more embodiments, the CPEs and/or the relative content of the CPEs and carbon nanotubes in the composite are effective to achieve an n-type conductivity of the composite between a source and a drain contact, wherein the n-type conductivity is at least 10 S cm⁻¹ or at least 100 S cm⁻¹. In one or more further embodiments, the CPEs and/or the relative content (of the CPEs and carbon nanotubes in the composite) are effective to achieve a p-type conductivity of the composite (between a source and a drain contact), wherein the p-type conductivity is at least 100 S cm⁻¹ or at least 500 S cm⁻¹.

The (e.g., flexible) device can comprise an organic electronic device (e.g., transistor, field effect transistor), organic optoelectronic device (e.g., light emitting diode, photovoltaic device), or thermoelectric device.

In one or more embodiments, the active region of the device comprises the composite, although the composite can be used in other layers such as hole injection layers or electron injection layers, or channel layers (of a transistor).

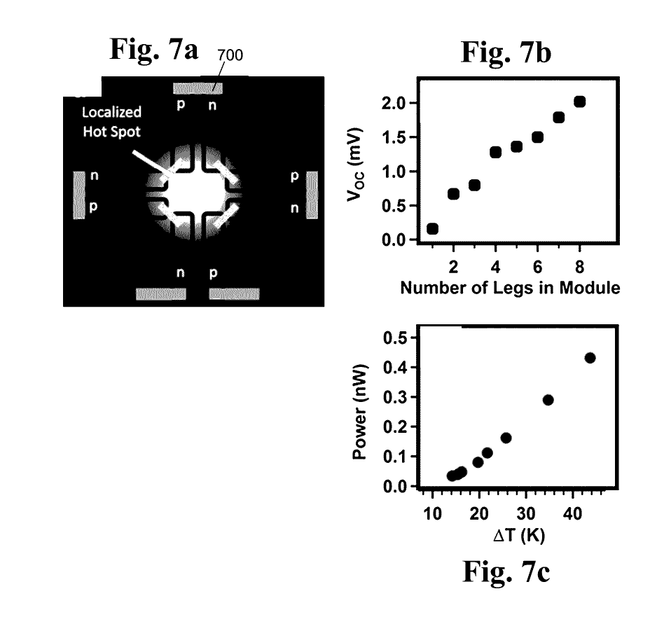

In one or more thermoelectric device embodiments, the composite generates electric current in response to a temperature gradient applied across the composite. The CPEs and the relative content of CPEs can be selected/effective to achieve a p-type doped composite having a power factor of at least 100 μW m⁻¹ K⁻² or at least 218 μW m⁻¹ K⁻² (e.g., using a 2:3 weight ratio of CPE-Na/SWNT). A power factor of at least 17 μW m⁻¹ K⁻² can be achieved in a thermoelectric device comprising an n-type doped composite (e.g., using a 1:1 weight ratio of CPE-PyrBIm₄/SWNT). A higher power factor for n-type flexible thermoelectric materials is described in Table S4 of the Supporting Information [23]. Furthermore, selective doping and solution processability of the composite can be controlled by the choice of CPE pendant charges to achieve thermoelectric devices requiring both p- and n-type materials. FIG. 7a illustrates a flexible, radial thermoelectric module fabricated using CPE-Na/SWNT (1:1) as p-legs and CPE-PyrBIm₄/SWNT (1:1) as n-legs on a flexible Kapton (polyimide) substrate and having metal contacts 700 (FIG. 7b shows open-circuit voltage (Voc) and FIG. 7c shows power generation for this module).

### Advantages and Improvements

It is unexpectedly found that careful tuning of the amount of CPE and nature of the CPE side chain (i.e., cationic or anionic side chain) can be used to select the majority carrier type in a composite with carbon nanotubes. The discovery is unexpected and surprising at least because improper selection of the relative amounts of CPEs and the carbon nanotubes undesirably reduces the conductivity (and harms other composite properties such as Seebeck coefficient, solution processability, and flexibility). Further information on one or more embodiments of the present invention can be found in reference [24].

### REFERENCES

The following references are incorporated by reference herein.
[1] a) C. Wang, K. Takei, T. Takahashi and A. Javey, Chem. Soc. Rev., 2013, 42, 2592; b) Park, S.; Vosguerichian, M. and Bao, Z. Nanoscale, 2013, 5, 1727.
[2] S. Niyogi, M. A. Hamon, H. Hu, B. Zhao, P. Bhowmik, R. Sen, M. E. Itkis and R. C. Haddon, Acc. Chem. Res., 2002, 35, 1105.
[3] a) H. Dai, E. W. Wong and C. M. Lieber, Science, 1996, 272, 523; b) S. Tans, M. Devoret, H. Dai and A. Thess, Nature, 1997, 386, 474; c) K. S. Novoselov, A. K. Geim, S. V. Morozov, D. Jiang, Y. Zhang, S. V. Dubonos, I. V. Grigorieva and A. A. Firsov, Science, 2004, 306, 666.
[4] M. M. J. Treacy, T. W. Ebbesen and J. M. Gibson, Nature, 1996, 381, 678; b) M. D. Lima, N. Li, M. J. de Andrade, S. Fang, S. J. Oh, G. M. Spinks, M. E. Kozlov, C. S. Haines, D. Suh, J. Foroughi, S. J. Kim, Y. Chen, T. Ware, M. K. Shin, L. D. Machado, A. F. Fonseca, J. D. W. Madden, W. E. Voit, D. S. Galvão and R. H. Baughman, Science, 2012, 338, 928.
[5] S. K. Samanta, M. Fritsch, U. Scherf, W. Gomulya, S. Z. Bisri and M. A. Loi, Acc. Chem. Res., 2014, 47, 2446.
[6] a) P. Deria, J.-H. Olivier, J. Park and M. J. Therien, J. Am. Chem. Soc., 2014, 136, 14193; b) Y. Li, C.-K. Mai, H. Phan, X. Liu, T.-Q. Nguyen, G. C. Bazan and M. B. Chan-Park, Adv. Mater., 2014, 26, 4697; c) P. Deria, C. D. V. Bargen, J.-H. Olivier, A. S. Kumbhar, J. G. Saven and M. J. Therien, J. Am. Chem. Soc., 2013, 135, 16220; d) T. Casagrande, P. Imin, F. Cheng, G. A. Botton, I. Zhitomirsky and A. Adronov, Chem. Mater., 2010, 22, 2741; e) F. Cheng, P. Imin, S. Lazar, G. A. Botton, G. de Silveira, O. Marinov, J. Deen and A. Adronov, Macromolecules, 2008, 41, 9869.
[7] a) V. Sgobba and D. M. Guldi, Chem. Soc. Rev., 2009, 38, 165; b) P. Singh, S. Campidelli, S. Giordani, D. Bonifazi, A. Bianco and M. Prato, Chem. Soc. Rev., 2009, 38, 2214.
[8] a) D. A. Heller, S. Baik, T. E. Eurell and M. S. Strano, Adv. Mater., 2005, 17, 2793; b) D. A. Heller, H. Jin, B. M. Martinez, D. Patel, B. M. Miller, T.-K. Yeung, P. V Jena, C. Höbartner, T. Ha, S. K. Silverman and M. S. Strano, Nat. Nanotechnol., 2009, 4, 114; c) Y. Liu, J. Huang, M.-J. Sun, J.-C. Yu, Y.-L. Chen, Y.-Q. Zhang, S.-J. Jiang and Q.-D. Shen, Nanoscale, 2014, 6, 1480; d) J. Budhathoki-Uprety, P. V Jena, D. Roxbury and D. A. Heller, J. Am. Chem. Soc., 2014, 136, 15545.
[9] a) S. Cataldo, P. Salice, E. Menna and B. Pignataro, Energy Environ. Sci., 2012, 5, 5940; b) D. D. Tune and J. G. Shapter, Energy Environ. Sci., 2013, 6, 2572; c) L. Wang, H. Liu, R. M. Konik, J. A. Misewich and S. S. Wong, Chem. Soc. Rev., 2013, 42, 8134.
[10] a) M. Shim, A. Javey, N. W. S. Kam and H. Dai, J. Am. Chem. Soc., 2001, 123, 11512; b) A. Javey, R. Tu, D. B. Farmer, J. Guo, R. G. Gordon and H. Dai, Nano Lett., 2005, 5, 345; c) J. Li, Y. Huang, P. Chen and M. B. Chan-Park, Chem. Mater., 2013, 25, 4464.
[11] Review: a) C. A. Hewitt and D. L. Carroll, Polymer Composites for Energy Harvesting, Conversion, and Storage, Ch. 9, 191-211, ACS Symposium Series, Vol. 1161, 2014; For selected examples: b) D. Kim, Y. Kim, K. Choi, J. C. Grunlan and C. Yu, ACS Nano, 2010, 4, 513; c) Q. Yao, L. Chen, W. Zhang, S. Liufu and X. Chen, ACS Nano, 2010, 4, 2445; d) W. Zhao, S. Fan, N. Xiao, D. Liu, Y. Y. Tay, C. Yu, D. Sim, H. H. Hng, Q. Zhang, F. Boey, J. Ma, X. Zhao, H. Zhang and Q. Yan, Energy Environ. Sci., 2012, 5, 5364; e) C. Yu, K, Choi, L. Yin and J. C. Grunlan, ACS Nano, 2011, 5, 7885; f) J. Liu, J. Sun, and L. Gao, Nanoscale, 2011, 3, 3616; g) C. Yu, A. Murali, K. Choi and Y. Ryu, Energy Environ. Sci., 2012, 5, 9481; h) D. D. Freeman, K. Choi and C. Yu, PLoS One, 2012, 7, e47822; i) G. P. Moriarty, J. N. Wheeler, C. Yu and J. C. Grunlan, Carbon, 2012, 50, 885; j) G. P. Moriarty, K. Briggs, B. Stevens, C. Yu and J. C. Grunlan, Energy Technol., 2013, 1, 265; k) Y. Nonoguchi, K. Ohashi, R. Kanazawa, K. Ashiba, K. Hata, T. Nakagawa, C. Adachi, T. Tanase and T. Kawai, Sci. Rep., 2013, 3, 3344.
[12] a) J. Kong, N. R. Franklin, C. Zhou, M. G. Chapline, S. Peng, K. Cho and H. Dai, Science, 2000, 287, 622; b) P. G. Collins, Science, 2000, 287, 1801; c) K. Bradley, S. Jhi, P. Collins, J. Hone, M. Cohen, S. Louie and A. Zettl, Phys. Rev. Lett., 2000, 85, 4361.
[13] Reviews: a) Y. Chen, Y. Zhao and Z. Liang, Energy Environ. Sci., 2015, 8, 401; b) B. T. McGrail, A. Sehirlioglu and E. Pentzer, Angew. Chem., Int. Ed., 2015, 2, 1710; c) Q. Zhang, Y. Sun, W. Xu and D. Zhu, Adv. Mater., 2014, 26, 6829; d) M. Culebras, C. Gómez and A. Cantarero, Materials, 2014, 7, 6701; e) M. He, F. Qiu and Z. Lin, Energy Environ. Sci., 2013, 6, 1352; f) O. Bubnova and X. Crispin, Energy Environ. Sci., 2012, 5, 9345; g) T. O. Poehler and H. E. Katz, Energy Environ. Sci., 2012, 5, 8110; h) N. Dubey and M. Leclerc, J. Polym. Sci. Part B Polym. Phys., 2011, 49, 467.
[14] Reviews: a) J. E. Anthony, A. Facchetti, M. Heeney, S. R. Marder and X. Zhan, Adv. Mater., 2010, 22, 3876; b) Q. Meng and W. Hu, Phys. Chem. Chem. Phys., 2012, 14, 14152; c) Y. Zhao, Y. Guo, Y. Liu, Adv. Mater., 2013, 25, 5372; d) X. Gao and Y. Hu, J. Mater. Chem. C, 2014, 2, 3099.
[15] R. S. Lee, H. J. Kim, J. E. Fischer and A. Thess, Nature, 1997, 388, 255.
[16] a) T. Takenobu, T. Takano, M. Shiraishi, Y. Murakami, M. Ata, H. Kataura, Y. Achiba and Y. Iwasa, Nat. Mater., 2003, 2, 683; b) T. Fukumaru, T. Fujigaya, N. Nakashima, Sci. Rep., 2015, 5, 7951.
[17] a) Z. B. Henson, Y. Zhang, T.-Q. Nguyen, J. H. Seo and G. C. Bazan, J. Am. Chem. Soc., 2013, 135, 4163; b) C.-K. Mai, H. Zhou, Y. Zhang, Z. B. Henson, T.-Q. Nguyen, A. J. Heeger and G. C. Bazan, Angew. Chem. Int. Ed., 2013, 52, 12874.
[18] a) H. Zhou, Y. Zhang, C.-K. Mai, S. D. Collins, T.-Q. Nguyen, G. C. Bazan and A. J. Heeger, Adv. Mater., 2014, 26, 780; b) H. Zhou, Y. Zhang, C.-K. Mai, J. Seifter, T.-Q. Nguyen, G. C. Bazan and A. J. Heeger, ACS Nano, 2015, 9, 371; c) H. Zhou, Y. Zhang, C.-K. Mai, S. D. Collins, G. C. Bazan, T.-Q. Nguyen and A. J. Heeger, Adv. Mater., 2015, 27, 1767.
[19] A. M. Glaudell, J. E. Cochran, S. N. Patel and M. L. Chabinyc, Adv. Energy Mater., 2015, 5, 1401072.
[20] C.-K. Mai, R. A. Schlitz, G. M. Su, D. Spitzer, X. Wang, S. L. Fronk, D. G. Cahill, M. L. Chabinyc and G. C. Bazan, J. Am. Soc. Chem., 2014, 136, 13478.
[21] a) B. Russ, M. J. Robb, F. G. Brunetti, P. L. Miller, E. E. Perry, S. N. Patel, V. Ho, W. B. Chang, J. J. Urban, M. L. Chabinyc, C. J. Hawker and R. A. Segalman, Adv. Mater., 2014, 26, 3473; b) R. A. Schlitz, F. G. Brunetti, A. M. Glaudell, P. L. Miller, M. A. Brady, C. J. Takacs, C. J. Hawker and M. L. Chabinyc, M. L. Adv. Mater., 2014, 26, 2825.
[22] M. S. Freund and B. A. Deore, Self-Doped Conducting Polymers, Wiley, Chichester, 2007.
[23] “Supporting Information for Doping Preferences in Conjugated Polyelectrolyte/Single-Walled Carbon Nanotube Composites,” by Cheng-Kang Mai and Guillermo C. Bazan. The supporting information provides detailed information on the synthesis/processing/fabrication of the composites and thermoelectric devices characterized in FIGS. 1-5 of this specification, as well as further thermoelectric measurements.
[24] “Varying the ionic functionalities of conjugated polyelectrolytes leads to both p- and n-type carbon nanotube composites for flexible thermoelectrics,” Cheng-Kang Mai, Boris Russ, Stephanie L. Fronk, Nan Hu, a Mary B. Chan-Park, Jeffrey J. Urban, d Rachel A. Segalman, Michael L. Chabinyc, and Guillermo C. Bazan, Energy Environ. Sci., 2015, 8, 2341 (supplementary information found in [23]).
[25] U.S. Pat. No. 9,293,708 B2, issued Mar. 22, 2016, by Guillermo C. Bazan, Lei Ying, Ben B. Y. Hsu, Wen Wen, Hsin-Rong Tseng, and Gregory C. Welch.
[26] Fullerene Additives Convert Ambipolar to p-Type Transport while Increasing the Operational Stability of Organic Thin Film Transistors”, by Michael J. Ford, Ming Wang, Hung Phan, Thuc-Quyen Nguyen, and Guillermo Bazan, Advanced Functional Materials, Volume 26, Issue 25, 4472-4480, Jul. 5, 2016.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method of fabricating a doped composite, comprising:
combining one or more carbon nanotubes with one or more Conjugated Polyelectrolytes (CPEs) to form a composite, wherein:
charge transfers between one or more of the CPEs and one or more of the carbon nanotubes, and
a relative content of the carbon nanotubes in the composite is selected such that the composite is n-type or p-type doped.

2. The method of claim 1, wherein the composite is n-type doped and has predominantly n-type conductivity.

3. The method of claim 1, wherein:
the combining further comprises:
coating a dispersion comprising the CPEs and the nanotubes on a substrate; and
annealing the dispersion to form a film; and
the relative content is such that an n-type conductivity of the film is at least 10 Siemens per centimeter.

4. The method of claim 3, wherein the n-type conductivity is at least 100 Siemens per centimeter.

5. The method of claim 1, wherein the composite is p-type doped and has predominantly p-type conductivity.

6. The method of claim 1, wherein:
the combining further comprises:
coating a dispersion comprising the CPEs and the nanotubes on a substrate; and
annealing the dispersion to form a film; and
the relative content is such that a p-type conductivity of the film is at least 100 Siemens per centimeter.

7. The method of claim 6, wherein the p-type conductivity is at least 500 Siemens per centimeter.

8. The method of claim 1, wherein the relative content is such that a ratio of a weight of the CPEs to a weight of the carbon nanotubes in the composite is between 1:1 and 2:3.

9. The method of claim 1, wherein the CPEs comprise a poly(cyclopenta-[2,1-b;3,4-b′]-dithiophene-alt-4,7-(2,1,3-benzothiadiazole)) (CPDT-alt-BT) backbone with anionic or cationic side groups.

10. The method of claim 9, wherein the CPEs comprise CPE-Na or the CPEs having a sulfonate side group.

11. The method of claim 9, wherein the CPEs comprise CPE-PyrBIm₄ or the CPEs having a pyridinium side group.

12. The method of claim 1, further comprising selecting the CPEs having cationic side groups and wherein the composite is n-type doped.

13. The method of claim 1, further comprising selecting the CPEs having anionic side groups and wherein the composite is p-type doped.

14. The method of claim 1, further comprising selecting the CPEs based on an optical bandgap, ionization energy, electron affinity, and/or dipole moment of the CPEs to achieve the composite having a desired n-type or p-type doping level.

15. The method of claim 1, further comprising selecting the anionic CPEs having anionic side groups and having |EA|>2.7 eV, and wherein the composite is p-type doped.

16. The method of claim 1, further comprising selecting the CPEs having cationic side groups and having IE<5.6 eV, and wherein the composite is n-type doped.

17. The method of claim 1, wherein the CPEs are doped in a solution prior to being combined with the carbon nanotubes.

18. The method of claim 1, wherein the combining comprises mixing the CPEs and nanotubes to form an aqueous mixture, the method further comprising casting the aqueous mixture on a substrate using spin-coating, drop-casting, or injection-printing to form a flexible electronic device or circuit.

19. The method of claim 18, wherein the CPEs increase solubility of, and/or act as a dispersant for, the carbon nanotubes in the aqueous mixture.

20. A doped composite, comprising:
a film including one or more carbon nanotubes coupled to one or more Conjugated Polyelectrolytes (CPEs), wherein:
charge transfers between one or more of the CPEs and one or more of the carbon nanotubes, and
a relative content of the carbon nanotubes in the composite is selected such that the composite is n-type or p-type doped.

21. The composite of claim 20, wherein:
the composite is processed from a dispersion cast on a substrate;
the dispersion comprises the CPEs and the nanotubes; and
the relative content is such that an n-type conductivity of the composite is at least 100 Siemens per centimeter.

22. The composite of claim 20, wherein:
the composite is processed from a dispersion cast on a substrate;
the dispersion comprises the CPEs and the nanotubes;
the relative content is such that an p-type conductivity of the composite is at least 500 Siemens per centimeter.

23. The composite of claim 20, wherein:
the CPEs have anionic side groups and |EA|>2.7 eV, and
the composite is p-type doped.

24. The composite of claim 20, wherein:
the CPEs have cationic side groups and IE<5.6 eV, and
the composite is n-type doped.

25. A thermoelectric device comprising the composite of claim 20, wherein:
the composite generates electric current in response to a temperature gradient applied across the composite, and
the CPEs and the relative content provide a thermoelectric performance for the device characterized by:
a power factor of at least 218 μW m⁻¹ K⁻² for a p-type doped composite, or
a power factor of at least 17 μW m⁻¹ K⁻² for an n-type doped composite.
